(19) United States
(12) Patent Application Publication
(10) Pub. No.: US 2025/0118699 A1
(43) Pub. Date: Apr. 10, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yoshiharu TAKADA, Nonoichi Ishikawa (JP)

(21) Appl. No.: 18/812,334

(22) Filed: Aug. 22, 2024

(30) Foreign Application Priority Data
Oct. 5, 2023 (JP) 2023-173732

(51) Int. Cl. H01L 23/00; H01L 23/31; H01L 23/495

(52) U.S. Cl. CPC H01L 24/40; H01L 23/3135; H01L 23/49555; H01L 24/37; H01L 24/32; H01L 24/73; H01L 2224/32245; H01L 2224/37011; H01L 2224/37013; H01L 2224/37147; H01L 2224/40175; H01L 2224/40499; H01L 2224/73263

(57) ABSTRACT

A semiconductor device includes a semiconductor element that includes a first electrode and a second electrode facing the first electrode in a first direction, a first conductor, and a first fixing member. The first conductor includes a first portion facing the first electrode in the first direction, and a second portion at least partially spaced apart from and facing the first portion in the first direction. The first fixing member is provided between the first electrode and the first portion, and between the first portion and the second portion in the first direction.

### CROSS-REFERENCE TO RELATED APPLICATION

This application is based upon and claims the benefit of priority Application No. 2023-173732, filed Oct. 5, 2023, the entire contents of which are incorporated herein by reference.

### FIELD

Embodiments described herein relate generally to a semiconductor device.

### BACKGROUND

A metal member referred to as, for example, a lead frame or a connector, is used in a structure for electrically connecting an electrode of a semiconductor element to the outside of a semiconductor package. The metal member and the semiconductor element are electrically connected via solder or the like.

### DESCRIPTION OF THE DRAWINGS

FIG. 1A is a top view of a semiconductor device according to a first embodiment.

FIG. 1B is a perspective view of the semiconductor device according to the first embodiment.

FIG. 2 is a cross-sectional view along line A-A′ shown in FIG. 1A.

FIG. 3A is a cross-sectional view of a semiconductor device according to a second embodiment.

FIG. 3B is a cross-sectional view of a semiconductor device according to a modification of the second embodiment.

FIG. 4 is a cross-sectional view of a semiconductor device according to a third embodiment.

FIG. 5 is a cross-sectional view of a semiconductor device according to a modification the third embodiment.

FIG. 6 is a cross-sectional view of a semiconductor device according to a fourth embodiment.

FIG. 7 is a cross-sectional view of the semiconductor device according to the fourth embodiment, along line B-B′ shown in FIG. 5.

FIG. 8 is a cross-sectional view of the semiconductor device according to a first modification of the third embodiment, along line B-B′ shown in FIG. 5.

FIG. 9 is a cross-sectional view of the semiconductor device according to a second modification of the third embodiment, along line B-B′ shown in FIG. 5.

FIG. 10 is a cross-sectional view of a semiconductor device according to a fifth embodiment.

FIG. 11 is a cross-sectional view of a semiconductor device according to a sixth embodiment.

FIG. 12 is a cross-sectional view of a semiconductor device according to a seventh embodiment.

FIG. 13 is a cross-sectional view of a semiconductor device according to a modification of the seventh embodiment.

### DETAILED DESCRIPTION

Embodiments provide a semiconductor device that protects against short-circuits.

In general, according to one embodiment, there is provided a semiconductor device including a semiconductor element that includes a first electrode and a second electrode facing the first electrode in a first direction, a first conductor, and a first fixing member. The first conductor includes a first portion facing the first electrode in the first direction, and a second portion at least partially spaced apart from and facing the first portion in the first direction. The first fixing member is provided between the first electrode and the first portion and between the first portion and the second portion.

According to another embodiment, there is provided a semiconductor device including a semiconductor element that includes a first electrode and a second electrode facing the first electrode in a first direction, a second conductor, a third conductor, and a first fixing member. The second conductor includes a fifth portion facing the first electrode in the first direction, and a sixth portion partially spaced apart from and facing the fifth portion in the first direction. The third conductor includes a seventh portion provided between the fifth portion and the sixth portion and at least partially in contact with the fifth portion and the sixth portion, and an eighth portion formed continuously with the seventh portion and spaced apart from the fifth portion in the first direction. The first fixing member is provided between the first electrode and the fifth portion, and at least partially between the fifth portion and the eighth portion.

Hereinafter, embodiments of the present disclosure will be described with reference to the drawings.

The drawings are schematic or conceptual, and the relationship between the thickness and width of each part, the size ratio between parts, and the like are not necessarily the same as those in reality. Even when the same part is represented, the dimension and ratio of each part may differ depending on the drawing.

For example, in the cross-sectional views shown in this specification of the present application, some stacked structures are shown, but the thickness ratios of the layers in the stacked structures are not necessarily the same as actual thickness ratios. Even when one layer is shown as being thicker than the other layer in the cross-sectional view, the thicknesses of one layer and the other layer may be approximately the same, or one layer may be thinner than the other layer in reality. That is, the dimensions such as thickness shown in the drawings in this specification may differ from the actual dimensions.

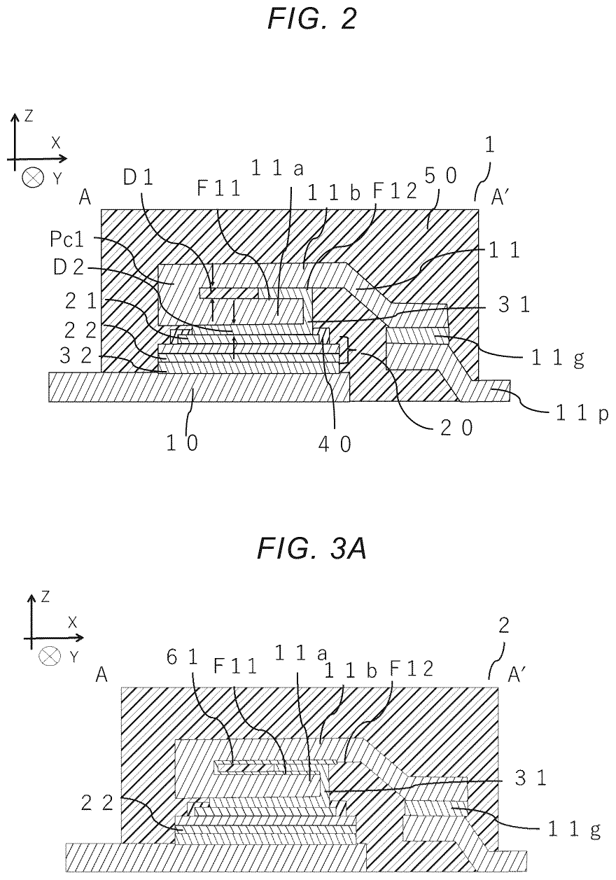

A direction from a second electrode 22 to a first electrode 21 is the Z-direction. A direction intersecting the Z-direction is the −X-direction, and a direction intersecting the X- and Z-directions is the Y-direction. A semiconductor device 1 shown in FIG. 2 is a cross-sectional view in the X-Z plane. The X-, Y-, and Z-directions are shown to be orthogonal to each other in the embodiments, but are not limited to being orthogonal to each other and may be in a mutually intersecting relationship. For the sake of description, a positive direction of the Z-direction is referred to as “up” and a negative direction of the Z-direction is referred to as “down”. However, the directions of “up” and “down” are not limited to the direction of gravity or the directions when the semiconductor device is mounted.

In this specification and each figure, elements similar to those described above with reference to the figures already mentioned are given the same reference numerals and detailed descriptions thereof are omitted as appropriate.

### First Embodiment

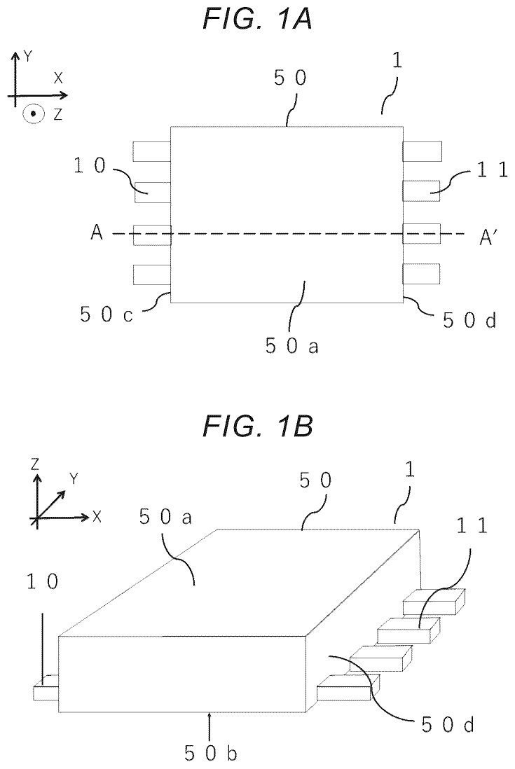

FIG. 1A is a top view showing the semiconductor device 1 according to a first embodiment. FIG. 1B is a perspective view showing the semiconductor device 1 according to the first embodiment. FIG. 2 is a cross-sectional view along line A-A′ shown in FIG. 1A. First, the semiconductor device 1 will be briefly described with reference to FIGS. 1A and 1B.

As shown in FIG. 1A, the semiconductor device 1 is sealed by a resin part 50. A part of a lead frame 10 or a first conductor 11 protrudes from the resin part 50 for electrical connection with the outside. The resin part 50 is, for example, a sealing resin containing an epoxy resin. The lead frame 10 and the first conductor 11 are formed of, for example, metal containing Cu.

FIG. 1A shows an example in which four protruding parts of lead frame 10 are provided on a first side surface 50c of the resin part 50, and four first conductors 11 are provided on a second side surface 50d facing the first side surface 50c in the X-direction. The number and shape of the protruding parts of lead frames 10 or the first conductors 11 are not limited to those shown in FIG. 1A. For example, three or less, or five or more, of the protruding parts of lead frames 10 or the first conductors 11 may be provided on the first side surface 50c or the second side surface 50d of the resin part 50, respectively. Furthermore, for example, the protruding parts of lead frames 10 or the first conductors 11 may be provided on a lower surface 50b facing an upper surface 50a of the resin part 50 in the Z-direction, or may be provided across the lower surface 50b and the first side surface 50c or the second side surface 50d.

Each protruding part of lead frame 10 and each first conductor 11 are electrically connected to a semiconductor element 20 shown later in FIG. 2. In FIG. 1A, the semiconductor element 20 is covered by the resin part 50 and is not shown. The lead frame 10 is connected to, for example, a drain electrode of the semiconductor element 20. The first conductor 11 is connected to, for example, a source electrode of the semiconductor element 20.

Some of the first conductors 11 protruding from the second side surface 50d may be connected to, for example, a gate electrode of the semiconductor element 20. In other words, among a plurality of first conductors 11 shown in FIG. 1A, some of the first conductors 11 may be connected to the source electrodes and some of the first conductors 11 may be connected to the gate electrodes. A portion of the first conductor 11 connected to the source electrode and a portion thereof connected to the gate electrode are electrically insulated.

As shown in FIG. 1B, a part of the lead frame 10 and a part of the first conductor 11 protrude from the resin part 50 and are used for electrical connection with the outside. The portions of the lead frame 10 and the first conductor 11 that protrude from the resin part 50 are referred to as terminals. A shape of each terminal is not limited to that shown in FIG. 1B, and may be, for example, a gull-wing type or a J type. The gull-wing type is a shape in which the terminal extending in the X-direction has a portion that is positioned differently in the Z-direction. That is, a step is provided so that the position in the Z-direction becomes lower toward the tip of the terminal.

Meanwhile, the J-type is a shape in which, for example, the terminal of the first conductor 11 is bent toward the negative direction of the Z-direction in the X-Z plane, and the tip of the terminal faces the negative direction of the X-direction. The appearance of the semiconductor device 1 has been described above with reference to FIGS. 1A and 1B.

Next, an internal wiring structure of the semiconductor device 1 will be described in detail with reference to FIG. 2.

FIG. 2 is a cross-sectional view along line A-A′ shown in FIG. 1A. As shown in FIG. 2, the semiconductor device 1 according to the first embodiment includes the lead frame 10, the first conductor 11, the semiconductor element 20, a first fixing member 31, a second fixing member 32, an insulator 40, and the resin part 50. The first conductor 11 has a first portion 11a and a second portion 11b.

The semiconductor element 20 includes the first electrode 21 and the second electrode 22. The second electrode 22 is provided on a surface opposite to the first electrode 21 in the Z-direction. The first electrode 21 and the second electrode 22 are formed of metal containing Ni, for example, and are coated with Au. The semiconductor element 20 is, for example, a MOSFET. The first electrode 21 is, for example, a source electrode. The second electrode 22 is, for example, a drain electrode.

In addition to the first electrode 21, which is, for example, the source electrode, and the second electrode 22, which is, for example, the drain electrode, the semiconductor element 20 may be provided with a gate electrode (not shown). The gate electrode is formed, for example, on the same surface of the semiconductor element 20 as a surface on which the first electrode 21 is provided, and is spaced apart from the first electrode 21. The gate electrode is electrically connected to the outside, for example, by a different conductor spaced apart from the first conductor 11, or by wire bonding or the like. The gate electrode is electrically insulated from the first electrode 21, and a different voltage can be applied thereto.

The first portion 11a faces the first electrode 21 of the semiconductor element 20 in the Z-direction. The first portion 11a has a first surface F11, which is a surface opposite to the surface facing the first electrode 21. The second portion 11b has a second surface F12 that is spaced apart from and faces the first surface F11 in the Z-direction.

The first conductor 11 has a connection portion Pc1 between the first portion 11a and the second portion 11b. The first portion 11a and the second portion 11b are connected through the connection portion Pc1. The first portion 11a and the second portion 11b may be integrally formed from a single conductive e structure. Here, the integrally formed structure denotes a seamless structure without any soldered connections. For example, the first portion 11a and the second portion 11b can be formed by bending the first conductor 11. The structure of the first conductor 11 shown in FIG. 2 can be formed by bending the first conductor 11 in the X-Z plane, for example. The first conductor 11 may have a U-shaped structure as shown in FIG. 2. Here, the connection portion Pc1 denotes a curved structure connecting the first portion 11a and the second portion 11b extending in directions intersecting the Z-axis so that the first portion 11a and the second portion 11b are at least partially spaced apart from and facing each other in the Z-direction. However, the structure of the first conductor 11 is not limited to the structure shown in FIG. 2, and the first portion 11a and the second portion 11b may be formed by bending the first conductor 11 in the Y-Z plane, for example.

The first fixing member 31 is provided between the first electrode 21 and the first conductor 11. The first fixing member 31 is further provided at least partially between the first surface F11 and the second surface F12 of the first conductor 11. For example, the first fixing member 31 electrically connects at least a part of the first surface F11 and the second surface F12 that are spaced apart in the Z-direction. The first fixing member 31 may be in contact with the first surface F11 and not in contact with the second surface F12. However, in order to reduce electrical resistance, it is desirable that the first fixing member 31 is in contact with the first surface F11 and the second surface F12, and the first surface F11 and the second surface F12 is electrically connected to each other. In the Z-direction, the first electrode 21, the first fixing member 31, the first portion 11a of the first conductor 11, the first fixing member 31, and the second portion 11b of the first conductor 11 are provided in this order. The first fixing member 31 electrically connects the first electrode 21 and the conductor 11.

The first fixing member 31, for example, continuously extends from on the first electrode 21 to between the first surface F11 and the second surface F12. For example, the first fixing member 31 is formed by melting the first fixing member 31 provided on the first electrode 21 and introducing the first fixing member 31 between the first surface F11 and the second surface F12 as a flow of the first fixing member 31 is molten form. The shape of the first fixing member 31 may be, for example, as shown in FIG. 2, a continuous shape surrounding the first portion 11a, or may be a shape that remains only on the first electrode 21 and on the first surface F11.

For example, in the manufacturing process, the molten first fixing member 31 is sucked between the first portion 11a and the second portion 11b after the first fixing member 31 reaches the first surface F11 with a continuous shape surrounding the first portion 11a, which may cause the first fixing member 31 to be formed discontinuously on the first electrode 21 and on the first surface F11.

The second fixing member 32 electrically connects the second electrode 22 and the lead frame 10. The second fixing member 32 may be formed of the same material as the first fixing member 31. For example, the first fixing member 31 and the second fixing member 32 are solder.

The first conductor 11 has a protruding part 11p protruding from the resin part 50. The second portion 11b and the protruding part 11p of the first conductor 11 are connected, for example, via a connecting part 11g, and form the first conductor 11 together with the first portion 11a. That is, in FIG. 2, the first conductor 11 has the first portion 11a, the second portion 11b, the connecting part 11g, and the protruding part 11p. The first portion 11a, the second portion 11b, and the protruding part 11p are formed, for example, of metal containing Cu, and the connecting part 11g is, for example, solder.

The protruding part 11p is made of, for example, the same material as the lead frame 10. The protruding part 11p has the structure shown in FIG. 2 by being cut from the lead frame 10 and bent, for example.

A portion of the first conductor 11 from the second portion 11b to the protruding part 11p may be integrally formed from a single conductive structure, for example. That is, the second portion 11b and the protruding part 11p may be formed continuously without providing the connecting part 11g. The second portion 11b and the protruding part 11p can be formed as one continuous member by bending the first conductor 11. Therefore, the first conductor 11 can also have at least the first portion 11a, the second portion 11b, and the protruding part 11p.

The insulator 40 is provided on at least a part of the first electrode 21 of the semiconductor element 20. The insulator 40 covers, for example, at least a part of an outer edge of the first electrode 21. Here, the outer edge is an outer peripheral portion of the first electrode 21 projected in the Z-direction. The insulator 40 is made of, for example, polyimide. The insulator 40 can protect the first electrode 21 from moisture and the like that could not be prevented by the resin part 50.

Except for a part of the lead frame 10 and the first conductor 11, the rest of the lead frame 10 and the first conductor 11 are sealed by the resin part 50. The resin part 50 is, for example, a sealing resin, and may contain an epoxy resin. The portion of the lead frame 10 and the first conductor 11 that is not sealed by the resin part 50 is used as the terminal shown in FIG. 1 for electrical connection to the outside.

A distance D1 in the Z-direction between the first surface F11 and the second surface F12 is, for example, 30 μm or less. A thickness D2 in the Z-direction of the first fixing member 31 provided between the first electrode 21 and the first portion 11a is, for example, 30 μm or less. The shape and dimensions shown in FIG. 2 are for convenience of illustration, and a size relationship between D1 and D2 is not limited to the dimensions shown in the figure. For example, D1 is approximately the same as or smaller than D2.

Since the purpose of the first fixing member 31 is to connect the first electrode 21 and the first portion 11a, it is desirable that the first fixing member 31 between the first electrode 21 and the first portion 11a is provided without excess or shortage. By forming D1 smaller than D2, the risk of insufficiency of the first fixing member 31 between the first electrode 21 and the first portion 11a can be reduced. This is because, when D1 is smaller than D2, the first fixing member 31 can be sufficiently provided between the first electrode 21 and the first portion 11a.

The electrical resistance of the first fixing member 31 that electrically connects the first electrode 21 and the first portion 11a decreases as the first fixing member 31 is provided more widely on the first electrode 21. That is, it is desirable that the first fixing member 31 is sufficient on the first electrode 21. Therefore, in order to make the connection between the first electrode 21 and the first portion 11a more reliable, it is desirable to set D1 to be smaller than D2. The first fixing member 31 can be formed between the first surface F11 and the second surface F12 while preventing the obstruction of the electrical connection between the first electrode 21 and the first portion 11a.

Furthermore, by setting D1 to be smaller, the first fixing member 31 is formed at a wider portion between the first and second portions 11a and 11b. By electrically connecting the first portion 11a and the second portion 11b over a wider portion via the first fixing member 31, the electrical resistance of the semiconductor device 1 can be reduced.

In order to prevent short-circuit due to the excess first fixing member 31, D1 needs to have a certain size or larger. In order to accommodate the excess first fixing member 31 between the first portion 11a and the second portion 11b, D1 must not be too small. That is, it is desirable to size D1 to be in a range where the excess first fixing member 31 can be accommodated between the first portion 11a and the second portion 11b.

In the following, an example of connecting the first electrode 21 and the first conductor 11 with the first fixing member 31 will be described while describing the manufacturing process of the semiconductor device 1. The first fixing member 31 is, for example, solder. First, the first fixing member 31 is temporarily fixed on the first electrode 21. Then, the first portion 11a of the first conductor 11 is provided on the first fixing member 31. At this time, the first fixing member 31 is not formed between the first portion 11a and the second portion 11b.

Next, the first fixing member 31 temporarily fixed is melted in a reflow process. The melted first fixing member 31 connects the first electrode 21 and the first portion 11a. In this reflow process, the melted first fixing member 31 flows between the first portion 11a and the second portion 11b, thereby obtaining the structure shown in FIG. 2.

In the reflow process, an amount of the first fixing member 31 may be greater than an amount thereof that can be accommodated between the first electrode 21 and the first portion 11a. That is, the first fixing member 31 may overflow from between the first electrode 21 and the first portion 11a. The first fixing member 31 overflowing from between the first electrode 21 and the first portion 11a flows between the first portion 11a and the second portion 11b, thereby preventing the first fixing member 31 from flowing out to the second electrode 22 of the semiconductor element 20.

As above, the configuration of the semiconductor device 1 according to the first embodiment was described with reference to FIGS. 1 and 2. The effects of the semiconductor device 1 according to this embodiment will be described below. In the semiconductor device 1 according to this embodiment, the first conductor 11 has the first portion 11a and the second portion 11b that are spaced apart from and face each other in the Z-direction. A space exists between the first portion 11a and the second portion 11b in the Z-direction. The first fixing member 31 is provided on the first electrode 21 and at least a part between the first portion 11a and the second portion 11b. The first fixing member 31 is provided at the space between the first portion 11a and the second portion 11b. That is, the first fixing member 31 spreads not only between the first electrode 21 and the first portion 11a but also between the first portion 11a and the second portion 11b, thereby preventing the first fixing member 31 from overflowing from the first electrode 21 toward the second electrode 22.

When connecting the first electrode 21 to the first conductor 11 by the first fixing member 31, a larger amount of the first fixing member 31 may be provided in order to avoid an increase in resistance due to poor connection. By providing a larger amount of the first fixing member 31, a gap between the first electrode 21 and the first conductor 11 can be reliably filled with the first fixing member 31, and an electrical connection can be established therebetween. However, for example, in a reflow process in which the temporarily fixed first fixing member 31 is melted, the first fixing member 31 may overflow from between the first electrode 21 and the first conductor 11.

Even when an excess of the first fixing member 31 occurs in this way, by allowing the first fixing member 31 to spread between the first portion 11a and the second portion 11b, it is possible to prevent the first fixing member 31 from spreading in a direction in which there is a risk of short-circuiting and thus impairing the reliability of the semiconductor device, for example, a direction of the second electrode 22 of the semiconductor element 20. As a result, the short-circuit caused by the first fixing member 31 going over the insulator 40 and reaching the second electrode 22 of the semiconductor element 20 can be prevented.

It is possible to provide the first portion 11a and the second portion 11b in the first conductor 11, for example, by bending the first conductor 11. The structure between the second portion 11b and the protruding part 11p is not limited to the shape shown in FIG. 2. In other words, if the first and second portions 11a and 11b are spaced apart from and face each other in the Z-direction, the effect of this embodiment can be obtained. For example, the shapes of the lead frame 10 and the semiconductor element 20 do not need to be changed. That is, this embodiment can be applied to conductors of various shapes, and thus to various semiconductor devices.

The insulator 40 protects the first electrode 21, but the adhesion between the insulator 40 and the first fixing member 31 may be inferior to that between the first conductor 11 and the first fixing member 31. The first fixing member 31 is, for example, solder, the first conductor 11 is, for example, Cu, and the insulator 40 is, for example, polyimide. Cu is superior to polyimide in terms of wettability with solder. In other words, Cu has a higher adhesion to solder than polyimide.

Since the adhesion between the insulator 40 and the first fixing member 31 is low, there is a risk that the first fixing member 31 is repelled from the insulator 40 and goes over the insulator 40 to cause short-circuit. Meanwhile, according to the semiconductor device 1 according to this embodiment, the first fixing member 31 can adhere to the first conductor 11, which has high adhesion, so that the solder can be prevented from being repelled by the insulator 40 and causing short-circuit.

The molten first fixing member 31 flows so as to surround the first conductor 11, which has higher adhesion than the insulator 40, and flows between the first portion 11a and the second portion 11b. The first fixing member 31 and the first conductor 11 also adhere to each other on at least one of the first surface F11 and the second surface F12, so that the first fixing member 31 can be prevented from going over the insulator 40. Therefore, the insulator 40 can both protect the first electrode 21 and prevent short-circuit caused by the first fixing member 31.

According to the semiconductor device 1 of this embodiment, by forming the first fixing member 31 between the first electrode 21 and the first portion 11a, and between the first portion 11a and the second portion 11b, short-circuit caused by the first fixing member 31 can be prevented. That is, the reliability of the semiconductor device can be improved.

### Second Embodiment

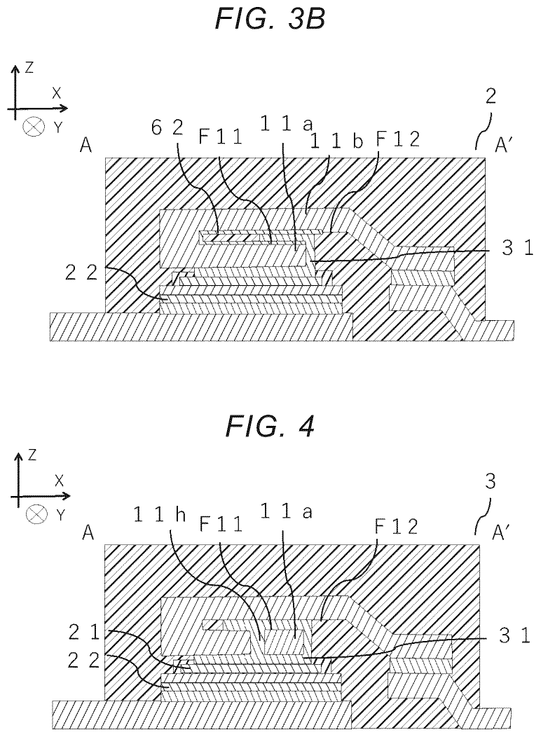

FIG. 3A is a cross-sectional view of a semiconductor device 2 according to a second embodiment. FIG. 3A shows a cross-section equivalent to A-A′ cross-section of FIG. 1A, which is a top view of the semiconductor device 1 according to the first embodiment. Therefore, in the following description, this cross-section and equivalent cross-sections across all embodiments is also referred to as an A-A′ cross-section for convenience. Description of some of the parts common to the semiconductor device 1 according to the first embodiment will be omitted, and only the different parts will be described.

As shown in FIG. 3A, a conductive film 61 is provided on a surface including at least a part of the first surface F11 of the first portion 11a and the second surface F12 of the second portion 11b. The conductive film 61 is superior to the first conductor 11 in terms of adhesion with the first fixing member 31. For example, the conductive film 61 has a higher wettability with the molten first fixing member 31 than the first conductor 11.

The conductive film 61 contains at least one metal species of, for example, Ni, Ag, and Sn. The conductive film 61 is formed, for example, by plating a part of a front surface of the first conductor 11.

The conductive film 61 may be formed continuously up to the portion of the first conductor 11 that contacts the connecting part 11g. For example, when forming the conductive film 61 by plating, it is desirable to plate the entire surface rather than masking and selectively plating the inside of the surface in order to reduce manufacturing costs.

The configuration of the semiconductor device 2 according to the second embodiment has been described above. The effects of the semiconductor device 2 according to the second embodiment will be described together with the effects of a modification of the second embodiment after the modification of the second embodiment is described.

### Modification of Second Embodiment

FIG. 3B is a cross-sectional view of the A-A′ cross-section of the semiconductor device 2 according to the modification of the second embodiment. Description of some of the parts common to the semiconductor device 2 according to the second embodiment will be omitted, and only the different parts will be described.

As shown in FIG. 3B, at least a part of the first surface F11 of the first portion 11a and the second surface F12 of the second portion 11b of the first conductor 11 is a rough surface part 62. The rough surface part 62 has a surface roughness greater than that of the original front surface of the first conductor 11. The rough surface part 62 can also be obtained by roughening a part of the front surface of the first conductor 11 by, for example, sandblasting. The rough surface 62 is superior to the first conductor 11 before treatment in terms of adhesion to the first fixing member 31. For example, the rough surface part 62 has a higher wettability with the molten first fixing member 31 than the first conductor 11 before treatment.

The effects of the semiconductor device 2 according to the second embodiment or the modification of the second embodiment will be described below. The semiconductor device 2 according to this embodiment includes the conductive film 61 or the rough surface part 62 that has excellent adhesion to the first fixing member 31. Therefore, compared to the semiconductor device 1 according to the first embodiment, the first fixing member 31 can be more strongly adhered between the first surface F11 and the second surface F12. Compared to the semiconductor device 1 according to the first embodiment, the adhesion is higher, and therefore the first fixing member 31 can be further prevented from going over the insulator 40. The excess first fixing member 31 can be further prevented from flowing toward the second electrode 22. That is, short-circuit can be prevented and reliability can be improved.

### Third Embodiment

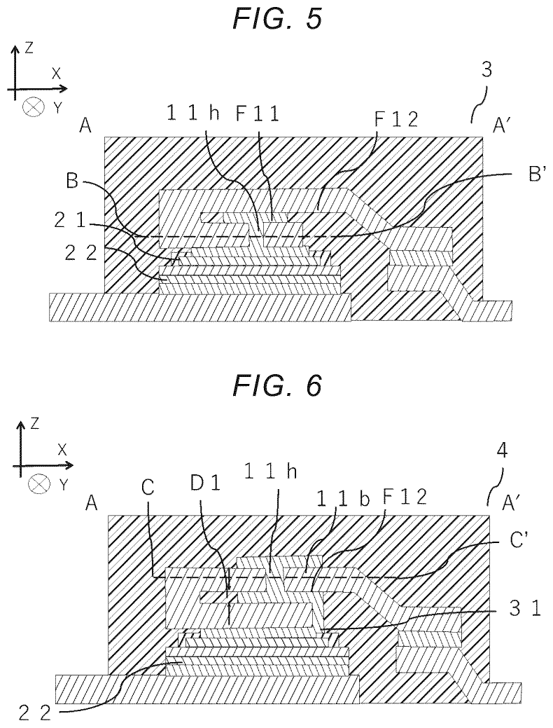

FIGS. 4 and 5 are cross-sectional views of the A-A′ cross-sections of a semiconductor device 3 according to a third embodiment. Description of some of the parts common to the semiconductor device 1 according to the first embodiment will be omitted, and only the different parts will be described. As shown in FIG. 4, in the semiconductor device 3 according to this embodiment, at least one first through hole 11h that penetrates the first portion 11a of the first conductor 11 in the Z-direction is provided.

The first fixing member 31 fills at least a part of the first through hole 11h. In order to prevent the increase in electrical resistance, it is desirable that all the first through holes 11h, if more than one is provided, are filled with the first fixing member. The first fixing member 31 provided on the first electrode 21 extends between the first portion 11a and the second portion 11b through the first through hole 11h.

As in the case shown in FIG. 4, the first fixing member 31 may be formed continuously so as to go around the first conductor 11. Meanwhile, as shown in FIG. 5, the first fixing member 31 may be formed in the gap between the first surface F11 and the second surface F12 through the first through hole 11h only. The B-B′ cross section shown in FIG. 5 will be described after the description of FIG. 6.

The effects of the semiconductor device 3 according to this embodiment will be described below. According to the semiconductor device 3 according to this embodiment, by providing the first through hole 11h, the first fixing member 31 is formed between the first surface F11 and the second surface F12 from on the first electrode 21 through the first through hole 11h. Therefore, compared to the semiconductor device 1 according to the first embodiment, the first fixing member 31 is more easily formed between the first surface F11 and the second surface F12.

According to the shape of the first fixing member 31 shown in FIG. 5, compared to the case of the shape of the first fixing member 31 shown in FIG. 2, the flow of the first fixing member 31 from the center to the outer edge of the first electrode 21 in the reflow process can be prevented. This is because the excess first fixing member 31 can pass through the first through hole 11h. Therefore, by suppressing the momentum of the first fixing member 31 flowing toward the outer edge of the first electrode 21, the risk of short-circuit due to the first fixing member 31 can be further reduced.

According to the semiconductor device 3 of this embodiment, by forming the first fixing member 31 between the first surface F11 and the second surface F12 through the first through hole 11h, the first fixing member 31 can be prevented from overflowing onto the second electrode 22 of the semiconductor element 20. That is, the reliability of the semiconductor device can be further improved.

### Fourth Embodiment

FIG. 6 is a cross-sectional view of the A-A′ cross-section of a semiconductor device 4 according to a fourth embodiment. Description of some of the parts common to the semiconductor device 1 according to the first embodiment will be omitted, and only the different parts will be described. As shown in FIG. 6, in the semiconductor device 4 according to this embodiment, the first through hole 11h that penetrates the second portion 11b of the first conductor 11 in the Z-direction is provided. The first fixing member 31 at least partially fills the first through hole 11h.

In order to prevent an increase in electrical resistance, it is desirable that all of the first through holes 11h, if more than one is provided, are filled with the first fixing member 31. When the first through holes 11h are filled with the first fixing member 31, electrical resistance can be reduced compared to when the insulating parts (like air gaps) exist in the first through holes 11h. The first fixing member 31 that passes through the first through hole 11h and is continuously formed on a surface opposite to the second surface F12 of the second portion 11b is covered with the resin part 50.

The effects of the semiconductor device 4 according to this embodiment will be described below. According to the semiconductor device 4 according to this embodiment, by providing the first through hole 11h, the first fixing member 31 can be formed continuously to the surface opposite to the second surface F12 of the second portion 11b through the first through hole 11h. Thus, the first fixing member 31 can be prevented from overflowing from the gap between the first surface F11 and the second surface F12.

Therefore, even if the first fixing member 31 used to connect the first electrode 21 and the first conductor 11 is excessive and cannot be accommodated in the gap between the first surface F11 and the second surface F12, the first fixing member 31 passes through the first through hole 11h and flows out to the surface opposite to the second surface F12 of the second portion 11b, so that the first fixing member 31 can be prevented from overflowing in the direction of the second electrode of the semiconductor element 20.

Furthermore, while reducing D1 is desirable for ensuring a reliable electrical connection between the first electrode 21 and the first portion 11a and for reducing the electrical resistance between the first portion 11a and the second portion 11b, there is a concern that by making D1 smaller, the excess first fixing member 31 is not accommodated between the first portion 11a and the second portion 11b. According to the semiconductor device 4 of this embodiment, the excess first fixing member 31 can be released above the second portion 11b through the first through hole 11h. Therefore, it is possible to reduce D1 while protecting against the risk of the first fixing member 31 overflowing.

According to the semiconductor device 4 of this embodiment, even when there are more first fixing members 31 than that of the semiconductor device 1 according to the first embodiment, it is expected that short-circuit caused by the first fixing members 31 can be prevented. In other words, it is possible to further increase the reliability of the semiconductor device.

The semiconductor device 4 according to the fourth embodiment has been described above. Next, the shape of the first through hole 11h common to the semiconductor device 3 according to the third embodiment described in FIGS. 4 and 5 and the semiconductor device 4 according to the fourth embodiment described in FIG. 6 will be further described.

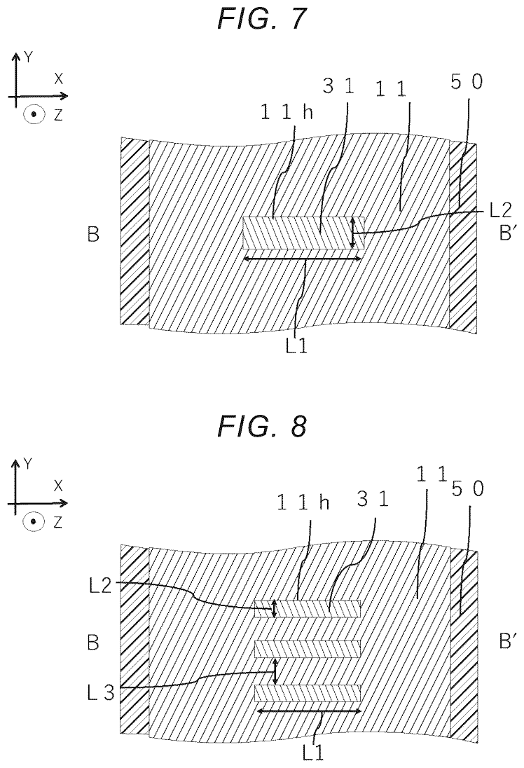

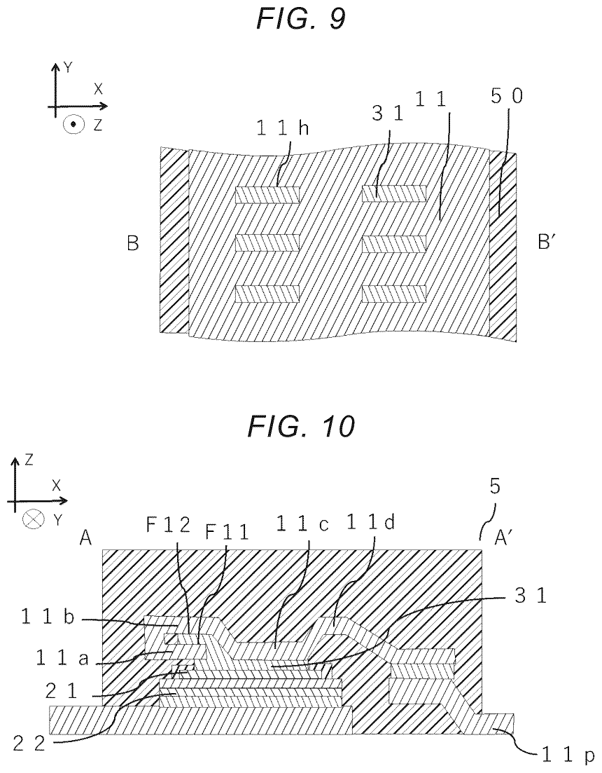

FIGS. 7, 8, and 9 show XY cross-sectional views along line B-B′ of FIG. 5. Also, FIGS. 7, 8, and 9 can be interpreted as XY cross-sectional views along line C-C′ of FIG. 6. FIG. 7 shows an example in which one first through hole 11h is provided. As shown in FIG. 8, a plurality of first through holes 11h may be provided in the direction (Y-direction) intersecting the direction from B to B′. Furthermore, as shown in FIG. 9, a plurality of first through holes 11h may also be provided in the direction from B to B′ (X-direction). The shape of the first through hole 11h is not limited to a rectangle as shown in FIGS. 7, 8 and 9, but may be, for example, an ellipse having no corners.

The first fixing member 31 filling at least a part of the first through hole 11h, and the first conductor 11 generally have different electrical conductivities. For example, the first fixing member 31 made of solder has lower electrical conductivity than that of the first conductor 11 made of Cu.

By providing the first through hole 11h in a manner such that the length in the Y-direction is shorter than the length in the X-direction, for example, as shown in FIG. 7, the current flowing in the direction from B to B′ (X-direction) mainly passes through the first conductor 11. Therefore, the increase in resistance can be prevented compared to the case where a width of the first through hole 11h is made larger in the direction (Y-direction) intersecting the direction from B to B′ (X-direction).

A length of the first through hole 11h in the direction from B to B′ (X-direction) is referred to as L1, and a length in the direction (Y-direction) intersecting therewith is referred to as L2. L1 is, for example, greater than L2. L1 may be greater than twice the L2 or greater than three times the L2.

Meanwhile, the wider the first through hole 11h is provided in the XY plane, the more efficiently the excess first fixing member 31 can pass through the first through hole 11h, and thus overflowing of the first fixing member 31 can be further prevented. That is, it is desirable to provide the first through hole 11h widely within the XY plane in order to prevent short-circuit. Meanwhile, the wider the first through hole 11h is provided, the more the electrical resistance between B-B′ increases when the electrical conductivity of the first fixing member 31 is lower than that of the first conductor 11. Since there is such a trade-off relationship when the first through holes 11h are provided, the arrangement and area of the first through holes 11h are optimized in order to prevent short-circuit and an increase in electrical resistance.

An example of a method for optimizing the arrangement and area of the first through holes 11h will be described with reference to FIG. 8. The first conductor 11 shown in FIG. 8 has multiple first through holes 11h in the Y-direction. A spacing between the first through holes 11h in the Y-direction is referred to as L3.

If L1 and L3 are fixed and L2 is increased, the area of the first through hole 11h becomes larger. Meanwhile, by increasing L2, a proportion of a current flowing in the X-direction that passes through the first conductor 11 decreases and the proportion of the current that passes through the first fixing member 31 increases, and thus there is a risk that the electrical resistance between B and B′ may increase.

Therefore, by simultaneously changing L1 and L2, it is possible to optimize both the area and the electrical resistance of the first through hole 11h. L1 can be made large so that the first fixing member 31 easily passes through the first through hole 11h in a wide range in the X-direction, while L2 can be made small so as to prevent the increase in electrical resistance.

L1 is, for example, greater than L2. L1 may be greater than twice the L2 or greater than three times the L2. L3 is, for example, greater than L2. L3 may be greater than twice the L2 or greater than three times the L2.

Furthermore, by increasing or decreasing the number of first through holes 11h in the Y-direction, and by increasing or decreasing L3, the area of the first through holes 11h in the XY plane can be increased or decreased.

That is, in the shape of the first through hole 11h shown in FIG. 8, by varying L1, L2, L3 and the number of first through holes 11h, the area of the first through holes 11h can be varied to optimize the ratio of the first fixing member 31 to the first conductor 11. By varying L1, L2, L3 and the number of first through-holes 11h, optimization can be performed so as to prevent short-circuit and keep the electrical resistance below a predetermined value.

As shown in FIG. 9, a plurality of first through-holes 11h can be divided and provided even in the X-direction.

According to the semiconductor device 3 according to the third embodiment described in FIG. 4 and FIG. 5, the first through hole 11h is at least partially filled with the first fixing member 31, and the excess first fixing member 31 spreads through the first through hole 11h, so that short-circuit failure caused by the first fixing member 31 can be prevented. The shape of the first through hole 11h can be determined so as to prevent an increase in electrical resistance due to the provision of the first through hole 11h. The same effect can also be obtained by the semiconductor device 4 according to the fourth embodiment described with reference to FIG. 6.

### Fifth Embodiment

FIG. 10 is a cross-sectional view of the A-A′ cross-section of a semiconductor device 5 according to a fifth embodiment. Description of some of the parts common to the semiconductor device 1 according to the first embodiment will be omitted, and only the different parts will be described. As shown in FIG. 10, in the semiconductor device 5 according to this embodiment, the first conductor 11 further has a third portion 11c. The third portion 11c is formed continuously with the second portion 11b.

In the first conductor 11, the first portion 11a, the second portion 11b, and the third portion 11c are formed in this order. That is, the third portion 11c is formed between the protruding part 11p and the second portion 11b. The first portion 11a, the second portion 11b, and the third portion 11c are, for example, integrally formed from a single conductive structure by bending the first conductor 11.

The first portion 11a faces the first electrode 21 in the Z-direction. The first surface F11 of the first portion 11a and the second surface F12 of the second portion 11b are spaced apart from and face each other in the Z-direction. The third portion 11c faces the first electrode 21 in the Z-direction.

The second portion 11b is located in a positive direction of the Z-direction relative to the first portion 11a. The second portion 11b is located in the positive direction of the Z-direction relative to the third portion 11c. The first portion 11a and the third portion 11c may be provided at the same height in the Z-direction. Here, the height refers to, for example, the distance measured from the first electrode 21 in the positive direction of the Z-direction. This is desirable because, by providing the first portion 11a and the third portion 11c at the same height in the Z-direction, the thickness of the first fixing member 31 in the Z-direction can be made uniform and the first conductor 11 can be provided flat on the first fixing member 31 between the first portion 11a and the first electrode 21 and between the third portion 11c and the first electrode 21.

The first fixing member 31 is provided between the first electrode 21 and the first portion 11a, between the first electrode 21 and the third portion 11c, and between the first portion 11a and the second portion 11b.

Furthermore, the first conductor 11 may have a fourth portion 11d, which is provided higher than the third portion 11c, between the third portion 11c and the protruding part 11p. The fourth portion 11d is continuously and integrally formed with, for example, the third portion 11c. By providing the fourth portion 11d higher than the third portion 11c, the risk of causing short-circuit is reduced between the fourth portion 11d and a portion of the semiconductor element 20 other than the first electrode 21 via the first fixing member 31. Therefore, the first conductor 11 desirably has the fourth portion 11d provided higher than the third portion 11c.

The effects of the semiconductor device 5 according to this embodiment will be described below. In the semiconductor device 5 according to this embodiment, the third portion 11c of the first conductor 11 is formed, for example, continuously between the protruding part 11p and the second portion 11b. According to the semiconductor device 5 of this embodiment, by forming the first fixing member 31 between the first portion 11a and the second portion 11b, the first fixing member 31 can be prevented from overflowing in the direction of the second electrode 22 of the semiconductor element 20. In particular, the first fixing member 31 can be prevented from reaching the second electrode 22 along a side surface of the semiconductor element 20 opposite to a side surface close to the protruding part 11p of the first conductor 11.

The semiconductor device 1 according to the first embodiment is superior to the semiconductor device! according to this embodiment in the effect of preventing the first fixing member from reaching the second electrode 22 along the side surface of the semiconductor element 20 close to the protruding part 11p of the first conductor 11. Meanwhile, the semiconductor device 5 according to this embodiment is superior to the semiconductor device 1 according to the first embodiment in the effect of preventing the first fixing member 31 from reaching the second electrode 22 along the side surface of the semiconductor element 20 opposite to the side surface close to the protruding part 11p of the first conductor 11. This is because the space into which the excess first fixing member 31 flows is located at a different position in the X-direction between the semiconductor device 1 according to the first embodiment and the semiconductor device 5 according to this embodiment.

Furthermore, in the semiconductor device 5 according to this embodiment, for a current flowing from the first electrode 21 to the first conductor 11, or a current flowing in the opposite direction, a path of the current passing through the first conductor 11 is shorter than that in the semiconductor device 1 according to the first embodiment. Current can flow from the first electrode 21 to the protruding part 11p through the first fixing member 31, the third portion 11c, and the fourth portion 11d.

For example, the first conductor 11 has higher electrical conductivity than that of the first fixing member 31. Therefore, in the semiconductor device 5 according to this embodiment, electrical resistance can be reduced by allowing the current to flow through a shorter path in the first conductor 11 compared to the semiconductor device 1 according to the first embodiment.

According to the semiconductor device 5 of this embodiment, it is possible to form a gap between the first portion 11a and the second portion 11b at a position in the X-direction different from that of the semiconductor device 1 of the first embodiment and to prevent short-circuit due to the first fixing member 31. Furthermore, a current can flow through a shorter path through the third portion 11c, and the electrical resistance can be reduced.

### Sixth Embodiment

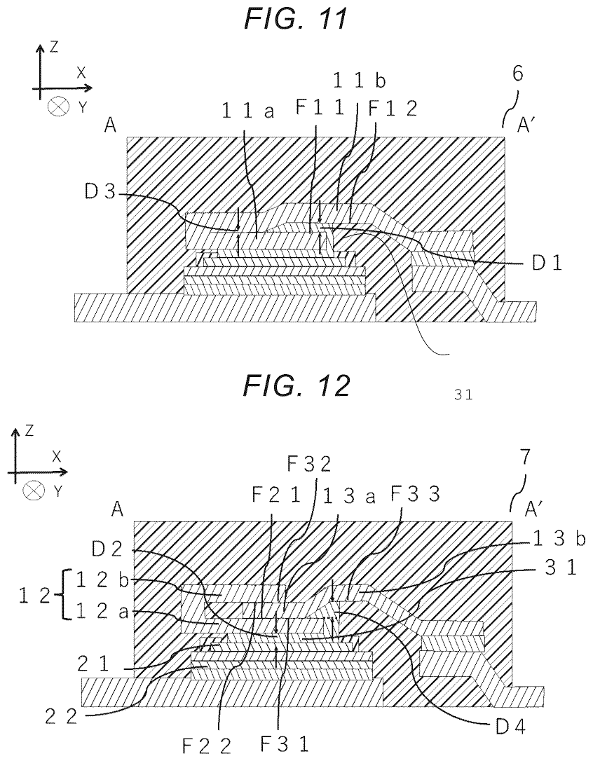

FIG. 11 is a cross-sectional view of the A-A′ cross-section of a semiconductor device 6 according to a sixth embodiment. Description of some of the parts common to the semiconductor device 1 according to the first embodiment will be omitted, and only the different parts will be described. As shown in FIG. 11, in the semiconductor device 6 according to this embodiment, the distance in the Z-direction between the first portion 11a and the second portion 11b of the first conductor 11 is not uniform.

The first fixing member 31 is provided at least partially between the first surface F11 and the second surface F12. The distance in the Z-direction between the first surface F11 and the second surface F12 is D1. D1 is, for example, 30 μm or less. Meanwhile, in a part of the second portion 11b, a distance D3 in the Z-direction from the first surface F11 is smaller than D1.

The distance in the Z-direction between the first portion 11a and the second portion 11b decreases in the negative direction of the X-direction, for example, as shown in FIG. 11. In other words, the gap between the first portion 11a and the second portion 11b narrows in the negative direction of the X-direction.

D3 may be small enough that the first and second portions 11a and 11b are electrically connected, for example, and the first portion 11a and the second portion 11b may be at least partially in contact with each other. The first portion 11a and the second portion 11b are partially electrically connected by being in contact with each other in a portion other than a portion where the first portion 11a and the second portion 11b are continuously formed by bending the first conductor 11.

A structure in which the first portion 11a and the second portion 11b are in contact with each other can be obtained, for example, by partially crushing the first conductor 11 having the structure shown in FIG. 2 in the Z-direction. The structure shown in FIG. 11 is obtained by selectively applying pressure to a portion on the negative side of the X-direction among portions where the first portion 11a and the second portion 11b face each other to crush the portion in FIG. 2, for example. For example, the structure shown in FIG. 11 extends in the Y-direction. In other words, the portion may be crushed by applying pressure in the Z-direction uniformly along the Y-direction.

A structure in which pressure is applied in the Z-direction partially along the Y-direction so that the first portion 11a and the second portion 11b come into contact with each other may be adopted. Although not shown in FIG. 11, for example, the first portion 11a and the second portion 11b may be in contact with each other at a part of an end of the gap between the first portion 11a and the second portion 11b on the positive side of the X-direction. That is, the first portion 11a and the second portion 11b may be brought into contact with each other by applying pressure in the Z-direction locally along the Y-direction.

If a gap is formed between the first portion 11a and the second portion 11b at least partially along the Y-direction, the first fixing member 31 can flow into the gap, and thus the effect of preventing short-circuit can be obtained. Since the first portion 11a and the second portion 11b can be brought into contact with each other over a wider area, the electrical resistance can be reduced.

The configuration of the semiconductor device according to the sixth embodiment has been described above. Next, the effects of the semiconductor device 6 according to this embodiment will be described. In the semiconductor device 6 according to this embodiment, the distance in the Z-direction between the first portion 11a and the second portion 11b is not uniform. By forming a gap of D3 smaller than D1, the gap between the first portion 11a and the second portion 11b can be filled with a smaller amount of the first fixing member 31 than in the semiconductor device 1 according to the first embodiment. Therefore, the portion where the first portion 11a and the second portion 11b are not electrically connected in the Z-direction is reduced, and the electrical resistance can be reduced.

Furthermore, by making D3 small enough that the first portion 11a and the second portion 11b are electrically connected, a flow path of the current can be made even shorter and the flow path can be made wider. Therefore, the electrical resistance between the first portion 11a and the second portion 11b is further reduced.

According to the semiconductor device 6 of this embodiment, the electrical resistance can be reduced by making the flow path of the current flowing from the first portion 11a to the second portion 11b or the current flowing in the opposite direction shorter or wider. That is, it is possible to provide a semiconductor device with lower resistance and improved performance.

Furthermore, according to the semiconductor device 6 of this embodiment, even when the amount of the first fixing member 31 exists between the first portion 11a and the second portion 11b is smaller than that of the semiconductor device 1 according to the first embodiment, the electrical connection between the first portion 11a and the second portion 11b is ensured.

In the semiconductor device 1 according to the first embodiment shown in FIG. 2, when the amount of the excess first fixing member 31 is not so large as to fill the space between the first portion 11a and the second portion 11b, it is conceivable that the sealing resin forming the resin part 50 flows between the first portion 11a and the second portion 11b. In addition, an air gap can also be formed between the first portion 11a and the second portion 11b. The more the sealing resin flows between the first portion 11a and the second portion 11b, the more the insulated portion increases, and therefore the electrical resistance between the first portion 11a and the second portion 11b increases.

Meanwhile, according to this embodiment, the space between the first portion 11a and the second portion 11b can be reduced by bringing a part of the second portion 11b into contact with the first portion 11a. Even when the amount of the excess first fixing member 31 is small, the gap into which the sealing resin forming the resin part 50 flows between the first portion 11a and the second portion 11b can be reduced.

According to the semiconductor device 6 of this embodiment, by making the distance between the first portion 11a and the second portion 11b in the Z-direction non-uniform, the electrical resistance to the current flowing through the first portion 11a and the second portion 11b can be reduced.

### Seventh Embodiment

FIG. 12 is a cross-sectional view along line A-A′ of a semiconductor device 7 according to a seventh embodiment. Description of some of the parts common to the semiconductor device 1 according to the first embodiment will be omitted, and only the different parts will be described. As shown in FIG. 12, the semiconductor device 7 according to this embodiment includes a second conductor 12 and a third conductor 13, instead of the first conductor 11.

The second conductor 12 has a fifth portion 12a that faces the first electrode 21 in the Z-direction. The fifth portion 12a faces the first electrode 21 in the Z-direction and is electrically connected thereto via the first fixing member 31. The fifth portion 12a has a third surface F21 on a side opposite to the surface that faces the first electrode 21 in the Z-direction.

The second conductor 12 has a sixth portion 12b that is spaced apart from and faces the fifth portion 12a in the Z-direction. A space exists between the fifth portion 12a and the sixth portion 12b in the Z-direction. The sixth portion 12b has a fourth surface F22. The fourth surface F22 is spaced apart from and faces the third surface F21 of the fifth portion 12a in the Z-direction.

The second conductor 12 is, for example, integrally formed from a single conductive structure, and the fifth portion 12a and the sixth portion 12b are made of the same material, for example, metal containing Cu.

The third conductor 13 has a seventh portion 13a. A fifth surface F31 of the seventh portion 13a of the third conductor 13 is at least partially in contact with the third surface F21. In other words, the third surface F21 of the second conductor 12 and the fifth surface F31 of the third conductor 13 are electrically connected in whole or at least in part on the surface.

The seventh portion 13a also has a sixth surface F32, which is the surface opposite to the fifth surface F31. The sixth surface F32 is at least partially in contact with the fourth surface F22 of the sixth portion 12b of the second conductor 12. That is, the fifth portion 12a and the sixth portion 12b of the second conductor 12, which are spaced apart in the Z-direction, are electrically connected to each other via the seventh portion 13a of the third conductor 13. The third surface F21 and the fifth surface F31 are in contact with each other, and the fourth surface F22 and the sixth surface F32 are in contact with each other.

The third conductor 13 has an eighth portion 13b in addition to the seventh portion 13a. For example, the eighth portion 13b is formed continuously and integrally with the seventh portion 13a. The eighth portion 13b has a seventh surface F33 that is continuous with the fifth surface F31 of the seventh portion 13a. The seventh surface F33 is provided in the positive direction of the Z-direction relative to the fifth surface F31. In other words, the third surface F21 and the seventh surface F33 are spaced apart in the Z-direction. A space exists between the fifth portion 12a and the eighth portion 13b in the Z-direction.

At least a part of the seventh surface F33 is in contact with the first fixing member 31. The first fixing member 31 is provided at least partially between the third surface F21 and the seventh surface F33 which are spaced apart in the Z-direction, and electrically connects the third surface F21 and the seventh surface F33. The first fixing member 31 is provided at the space between the fifth portion 12a and the eighth portion 13b in the first direction.

A distance D4 in the Z-direction between the third surface F21 and the seventh surface F33 is approximately the same as or smaller than a distance D2 between the first electrode 21 and the fifth portion 12a. Here, D4 is defined as the maximum value when a distance between the third surface F21 and the seventh surface F33 is not constant in the X-direction. D4 is, for example, 30 μm or less.

The effects of the semiconductor device 7 according to this embodiment will be described below. According to the semiconductor device 7 of this embodiment, the first connecting member 31 is formed in the gap created by the separation in the Z-direction between the third surface F21 of the second conductor 12 and the seventh surface F33 of the third conductor 13 and the first fixing member 31 is prevented from overflowing, thereby capable of preventing short-circuit failure caused by the first connecting member 31.

Furthermore, as with the semiconductor device 6 according to the sixth embodiment, the electrical resistance can be reduced by shortening and widening the current path compared to the semiconductor device according to the first embodiment. That is, since the second conductor 12 and the third conductor 13 are electrically connected to each other by the third surface F21 and the fifth surface F31 being in contact with each other, it is possible to shorten and widen the flow path of the current flowing from the first electrode 21 to the third conductor 13 via the second conductor 12, or the current flowing in the opposite direction.

Furthermore, it is possible to form the gap between the third surface F21 and the seventh surface F33 into which the first fixing member 31 flows so as to be narrower in the negative direction of the X-direction. In the sixth embodiment, the shape of the gap controlled by crushing a part of the first conductor 11. In the manufacturing method in which the first conductor 11 is crushed in the Z-direction, the malleability of the material of the first conductor 11 may be affected by environmental changes such as temperature, and the structure finally obtained may be affected by deviations in the crushing position.

Meanwhile, in the structure according to this embodiment, the shape of the gap into which first fixing member 31 flows is controlled by the shape of the third conductor 13. The shape of the third conductor 13 can be molded, for example, using a mold. Therefore, according to this embodiment, the gap into which the first fixing member 31 flows can be controlled more precisely than in the sixth embodiment.

According to the semiconductor device 7 of this embodiment, the short-circuit failure due to the first fixing member 31 can be prevented and electrical resistance can be reduced. Furthermore, it is possible to precisely control the shape of the gap into which the first fixing member 31 flows by controlling the shape of the third conductor 13.

### Modification of Seventh Embodiment

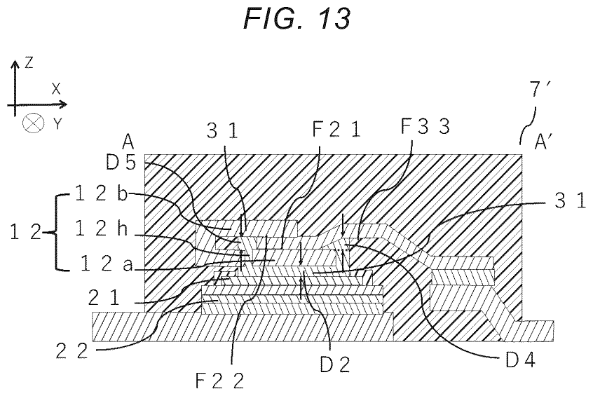

A semiconductor device 7′ which is a modification of the semiconductor device 7 according to the seventh embodiment will be described below. Description of some of the parts common to the semiconductor device 7 according to the seventh embodiment will be omitted, and only the different parts will be described. FIG. 13 is a cross-sectional view of the A-A′ cross-section of the semiconductor device 7′ which is a modification of the semiconductor device 7 of the seventh embodiment.

In this modification, a second through hole 12h which penetrates the fifth part 12a of the second conductor 12 in the Z-direction is provided. The first fixing member 31 reaches the third surface F21 of the second conductor 12 on the first electrode 21 through the second through hole 12h. The first fixing member 31 may further reach the fourth surface F22 of the sixth portion 12b of the second conductor 12.

Regarding the shape and arrangement of the second through hole 12h in the XY plane, various arrangements, which are similar to those shown in FIGS. 7, 8, and 9, are possible

D4 is approximately the same as or smaller than D2. A distance D5 in the Z-direction between the third surface F21 and the fourth surface F22 is approximately the same as or smaller than D2. D5 is, for example, 30 μm or less. By setting D4 and D5 to lengths approximately the same as or smaller than D2, the risk of a shortage of the first fixing member 31 between the first electrode 21 and the fifth portion 12a can be reduced.

The effects of the modification of the semiconductor device 7′ according to the seventh embodiment will be described below. In the semiconductor device 7′ according to this modification, the third surface F21 of the second conductor 12 and the seventh surface F33 of the third conductor 13 are spaced apart in the Z-direction, and the third surface F21 of the second conductor 12 and the fourth surface F22 are spaced apart. At least a part of each of these gaps is filled with the first fixing member 31. The first fixing member 31 fills at least a part of the gap provided between the second conductor 12 and the third conductor 13 near both ends of the semiconductor element 20 in the positive direction and the negative direction of the X-direction. That is, the first fixing member 31 can be prevented from overflowing on both sides in the positive direction and the negative direction of the X-direction.

According to the semiconductor device 7′ of this modification, the first fixing member 31 can be prevented from overflowing on both sides in the positive direction and the negative direction of the X-direction. Short-circuit caused by the first fixing member 31 can be prevented on the side surfaces of the semiconductor element 20 in both directions of the x-direction, and the reliability of the semiconductor device can be improved.

According to at least one of the embodiments described above, by forming the first fixing member 31 at least partially in the gap provided in the first conductor 11, the second conductor 12, or the third conductor 13, the first fixing member 31 can be prevented from overflowing in the direction of the second electrode 22. By preventing short-circuit due to the first fixing member 31, the reliability of the semiconductor device can be improved.

As above, the embodiments were described with reference to specific examples. However, the embodiments are not limited to these specific examples. That is, those obtained by appropriately modifying the design of these specific examples by a person skilled in the art also fall within the scope of the embodiments as long as they have the characteristics of the embodiments. The elements of each of the specific examples described above, as well as their arrangement, materials, conditions, shapes, sizes, and the like are not limited to those exemplified and can be appropriately changed.

The elements of each of the embodiments described above can be combined to the extent technically possible, and combinations of these elements also fall within the scope of the embodiments as long as they have the characteristics of the embodiments. In addition, within the scope of the idea of the embodiments, a person skilled in the art may conceive of various modifications and alterations, and it is understood that these modifications and alterations also fall within the scope of the embodiments.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a lead frame;
a semiconductor element including
a first electrode and
a second electrode electrically connected to the lead frame, provided on a surface opposite to the first electrode in a first direction;
a first conductor including
a first portion facing the first electrode in the first direction, and
a second portion at least partially spaced apart from and facing the first portion in the first direction; and
a first fixing member provided between the first electrode and the first portion and between the first portion and the second portion in the first direction.

2. The semiconductor device according to claim 1, wherein
the first conductor has a connection portion between the first portion and the second portion.

3. The semiconductor device according to claim 1, wherein
the first conductor is integrally formed from a single conductive structure.

4. The semiconductor device according to claim 1, wherein
the first conductor is formed of metal containing Cu, and
the first fixing member is formed of solder.

5. The semiconductor device according to claim 1, further comprising:
an insulator that covers an edge of the first electrode.

6. The semiconductor device according to claim 1, wherein
at least a part of a first surface, which is a surface of the first portion opposite to a surface facing the first electrode, and a second surface of the second portion at least partially spaced apart from and facing the first surface in the first direction is coated with a first metal species different from that of the first conductor.

7. The semiconductor device according to claim 6, wherein
the first conductor is formed of metal containing Cu, and
the first metal species include at least one of Ni, Ag, and Sn.

8. The semiconductor device according to claim 1, wherein
a surface roughness of at least a part of a first surface, which is a surface of the first portion opposite to a surface facing the first electrode, and a second surface of the second portion at least partially spaced apart from and facing the first surface in the first direction is greater than that of the other portions of the first conductor.

9. The semiconductor device according to claim 1, wherein
the first conductor has a first through hole that penetrates the first portion in the first direction, and
the first fixing member fills at least a part of the first through hole.

10. The semiconductor device according to claim 9 wherein
the first through hole is filled with the first fixing member.

11. The semiconductor device according to claim 1, wherein
the first conductor has a first through hole that penetrates the second portion in the first direction, and
the first fixing member fills at least a part of the first through hole.

12. The semiconductor device according to claim 11 wherein
the first through hole is filled with the first fixing member.

13. The semiconductor device according to claim 1, wherein
the first conductor has a plurality of through holes that penetrate the first portion in the first direction, and
each of the plurality of through holes is filled with the first fixing member.

14. The semiconductor device according to claim 1, wherein
the first conductor has a third portion formed continuously with the second portion,
the third portion faces the first electrode via the first fixing member, and
a distance between the third portion and the first electrode in the first direction is less than a distance between the second portion and the first electrode in the first direction.

15. The semiconductor device according to claim 1, wherein
the first portion and the second portion of the first conductor are at least partially in contact with each other.

16. A semiconductor device comprising:
a lead frame;
a semiconductor element including
a first electrode and
a second electrode electrically connected to the lead frame, provided on a surface opposite to the first electrode in a first direction;
a first conductor including
a first portion facing the first electrode in the first direction, and
a second portion at least partially spaced apart from and facing the first portion in the first direction; and
a first fixing member electrically connecting the first electrode and the first conductor,
wherein the first electrode, the first fixing member, the first portion, the first fixing member, and the second portion are provided in this order in the first direction.

17. The semiconductor device according to claim 16, further comprising:
an insulator on the semiconductor element that covers an edge of the first electrode and separates the first fixing member and the second electrode.

18. A semiconductor device comprising:
a lead frame;
a semiconductor element including
a first electrode and
a second electrode electrically connected to the lead frame, provided on a surface opposite to the first electrode in a first direction;
a first conductor including
a first portion facing the first electrode in the first direction, and
a second portion at least partially spaced apart from and facing the first portion in the first direction;
a second conductor including
a third portion provided between the first portion and the second portion and at least partially in contact with the first portion and the second portion, and
a fourth portion connected to the third portion and spaced apart from the first portion in the first direction; and
a first fixing member provided at least partially between the first electrode and the first portion and provided between the first portion and the fourth portion in the first direction.

19. The semiconductor device according to claim 18, wherein the first fixing member provided between the first portion and the fourth portion in the first direction has a height in the first direction that is maximum at an edge of the first fixing member and gradually decreases in a second direction that crosses the first direction and is oriented towards the first conductor.

20. The semiconductor device according to claim 19, wherein the first conductor has a through hole that penetrates the first portion and is filled with the first fixing member.
